(19) United States
(12) Patent Application Publication
(10) Pub. No.: US 2024/0348236 A1
(43) Pub. Date: Oct. 17, 2024

(54) RECONFIGURABLE MANIFOLD COMBINERS

(71) Applicant: DIELECTRIC, LLC, Raymond, ME (US)

(72) Inventors: Keith PELLETIER, Raymond, ME (US); Derek J. SMALL, Raymond, ME (US)

(21) Appl. No.: 18/630,613

(22) Filed: Apr. 9, 2024

Related U.S. Application Data
(60) Provisional application No. 63/458,787, filed on Apr. 12, 2023.

(51) Int. Cl. H03H 17/02

(52) U.S. Cl. CPC H03H 17/0266

(57) ABSTRACT

A manifold combiner for a multi-station broadcast site uses adjustable and/or interchangeable manifold segments for rapid reconfiguration, e.g., in accordance with pre-determined plans for contingent operations such as addition or removal of stations and responses to equipment malfunction. Plural reconfigurable manifold combiners can be joined via one or more hybrids couplers to produce a single antenna feed. Via, e.g., rectilinear arrangements of manifold in a single plane, adjustments may be achieved without moving filter equipment.

### CROSS-REFERENCE TO RELATED APPLICATIONS

This application claims priority to U.S. Provisional Application No. 63/458,787, filed 12 Apr. 2023, entitled “Reconfigurable Manifold Combiner,” the disclosure of which is hereby incorporated by reference in its entirety.

### TECHNICAL FIELD OF THE INVENTION

The present invention relates to radio frequency (RF) electromagnetic signal broadcasting, including techniques for combining multiple high-level broadcast signals for transmission from a single transmitting antenna.

### BACKGROUND

U.S. Pat. No. 7,864,001 (Downs, et al.), titled “Manifold combiner for multi-station broadcast sites apparatus and method,” granted Jan. 4, 2011, describes a manifold combiner for a plurality of radio frequency (RF) electromagnetic signals that includes a first RF bandpass filter element with input and output ports and a first junction element, wherein the first junction element includes a first port connected to the first filter output port, a second port connected to a shorted stub element, and a third port functioning as an output. The signal path toward the stub appears as an open to the first filter. The combiner further includes at least one additional filter element and junction element, with the second port of the additional junction element fed from the output of the previous junction element. Interconnecting sections couple the respective elements. Dimensions of interconnecting sections are selected such that each filter element output sees a single path out of the manifold, through the output of the last junction element, with all other possible paths appearing as open circuits. The content of U.S. Pat. No. 7,864,001 is hereby incorporated by reference in its entirety.

### SUMMARY

A manifold combiner for a multi-station broadcast site is arranged for rapid reconfiguration through the use of adjustable and/or interchangeable manifold segments.

Segments and/or plans can be pre-determined for a variety of configurations of a multi-station broadcast site. For example, plans can be predetermined for the addition or removal of stations, and/or for contingent swapping of equipment elements for use by different stations in the event of malfunction of equipment elements. For example, a plurality of contingent configurations can be determined experimentally prior to commissioning a multi-station broadcast site, and the site can be equipped with adjustable or alternative manifold segments that can be interchanged rapidly when required.

A site using a reconfigurable manifold combiner can be initially provided with unused ports for future use for additional channels and/or as in-place backups for used channels.

Plural reconfigurable manifold combiners can be joined via one or more hybrids couplers to produce a single antenna feed.

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter. Furthermore, the claimed subject matter is not limited to limitations that solve any or all disadvantages noted in any part of this disclosure.

### BRIEF DESCRIPTION OF THE DRAWINGS

FIGS. 1-3 are schematic representations of mechanical configurations of filters and manifold elements.

FIG. 1 is a front view of a bank of seven radio channel filters.

FIG. 2 is a front view of the bank of filters of FIG. 1 fitted with a reconfigurable manifold combiner.

FIG. 3 illustrates a top view of an optional arrangement of the bank of filters of FIGS. 1 and 2, wherein the filters for channels B and F are not presently connected to the reconfigurable manifold combiner.

FIGS. 4-10 are perspective views of configurations of filters and manifold elements. The figures are not necessarily drawn to scale.

FIG. 4 shows an initial configuration five filters connected to a manifold combiner, and spaces for two more filters, such that seven filters can be abutted side-by-side and connected to the manifold combiner.

FIG. 5 shows the removal of a stub to make room for a Channel B filter.

FIG. 6 shows the Channel B filter being added.

FIG. 7 shows reconfiguration of the manifold combiner and installation of the Channel B filter.

FIG. 8 shows the removal of a stub in the space for a Channel F filter.

FIG. 9 shows the Channel F filter being moved into place.

FIG. 10 shows reconfiguration of the manifold combiner and nearly complete installation of the Channel F filter.

FIG. 11 is a perspective view of an installation with a dual reconfigurable manifolds feeding into an output hybrid coupler.

FIG. 12 is a schematic of the hybrid coupler of FIG. 11.

FIG. 13 is a schematic of three hybrids which join feeds from four reconfigurable manifolds.

### DETAILED DESCRIPTION

A manifold combiner for a multi-station radio broadcast site can be arranged for rapid reconfiguration through the use of adjustable and/or interchangeable manifold segments. Many aspects of the techniques and advantages of manifold combiners are described in U.S. Pat. No. 7,864,001 (Downs, et al.), titled “Manifold combiner for multi-station broadcast sites apparatus and method.” Manifold combiners can be arranged to be dynamically reconfigurable using techniques described herein. See also Small, Derek J., “Reconfigurable Manifold Combiner,” National Association of Broadcasters 2023 BEITC Proceedings, Apr. 14, 2023.

Traditionally, when looking at expanding a filter system for the addition of new channels, a constant impedance module (CIF) would be used. Reconfigurable combiner technology allows for expansion and/or modification of installations without the use of the CIF. For example, reconfiguration of a manifold combiner can be facilitated through the use of pre-determination of plans for various configurations for a multi-station broadcast site. Alternative segments of manifolds can be prefabricated for switching into position to rapidly adjust manifold operations in accordance with such a plan. Additionally, or alternatively, segments of the manifold can be arranged to have variable lengths, whereby their electrical properties can be adjusted by modifying their lengths in situ in a manifold.

Plans can be predetermined for the addition or removal of radio station channel, and/or for contingent swapping of equipment elements for use by different stations in the event of malfunction of equipment elements. Similarly, a plurality of contingent configurations can be determined experimentally prior to commissioning a multi-station broadcast site, and the site can be equipped with adjustable and/or alternative manifold segments that can be adjusted or interchanged rapidly when required.

A site using a reconfigurable manifold combiner can be initially implemented with unused ports that can be used for additional channels and/or as in-place backups for channels in use. Reconfiguration parameters, such which lengths of manifold sections to use at various locations can be determined prior to the need for configuration, e.g., either by simulation, experimentation, or combinations thereof.

### Example Reconfigurable Manifold Combiner Implementation

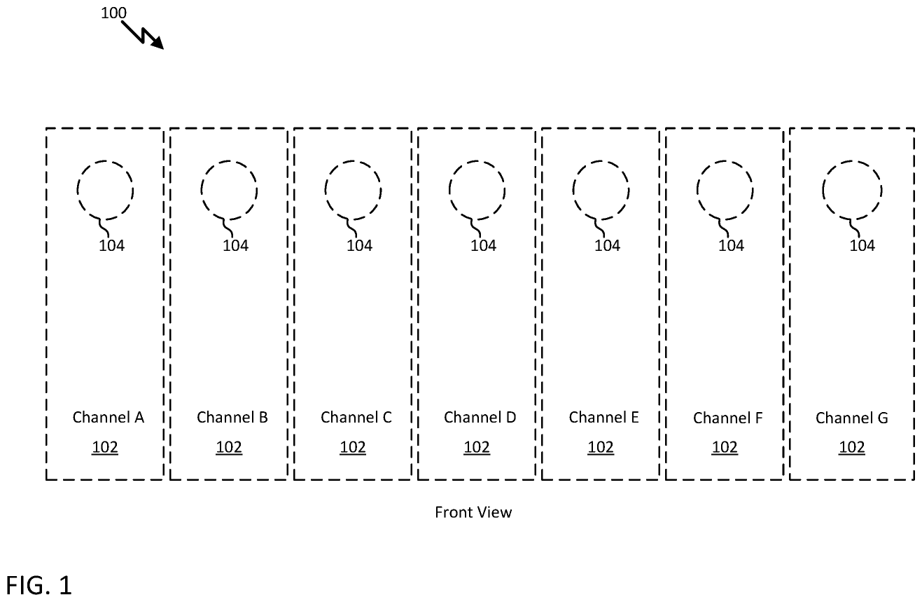

FIG. 1 is a schematic front view of a bank 100 of seven bandpass filters 102 for seven radio Channels A through G. The bank can be located, for example, at a multi-station broadcast site where seven radio stations broadcast from a shared tower. In practice, the techniques described herein can be applied in any radio spectrum range, e.g., via in adjustments to the sizes of manifolds, and for any number of channels, depending on mechanical limitations of manifold construction and acceptable interference limits between channels.

In the example of FIG. 1, an output port 104 for each filter 102 is visible. These ports 104 can be connected to each other and connected to a broadcast tower via a reconfigurable manifold combiner. The tower and the reconfigurable manifold combiner are not shown in FIG. 1.

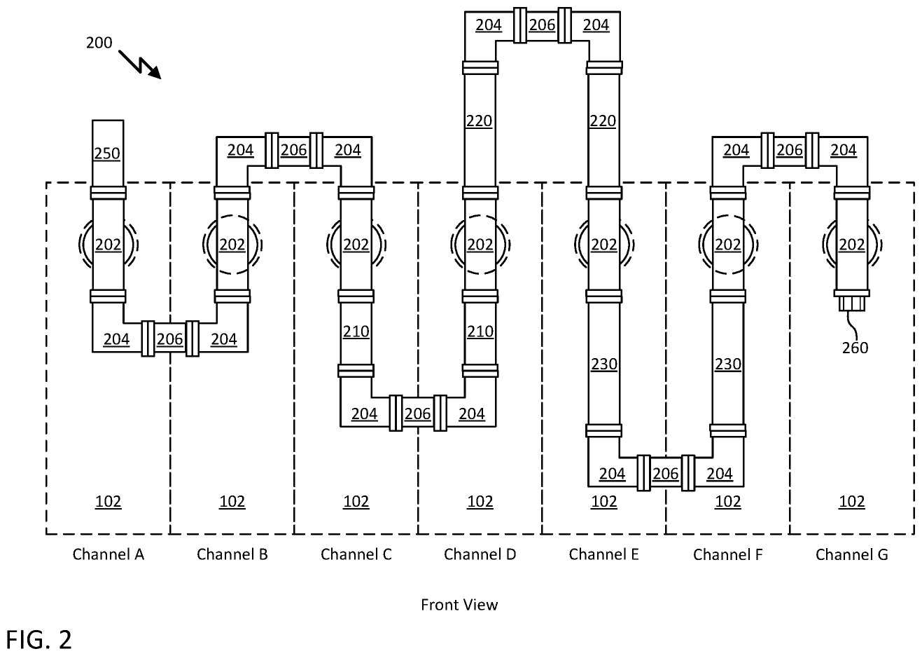

FIG. 2 illustrates a system 200 include the bank 100 of seven filters 102 of FIG. 1 plus a reconfigurable manifold combiner made up of filter connector sections 204, elbow sections 206, horizontal connectors 206, and vertical adjustment sections 210, 220, and 230. In the FM band, for example, such sections can be rigid coaxial sections. It will be appreciated that alternatives include flexible coax, waveguides, and the like as appropriate in various applications and frequency ranges

Atop the filter connector 204 for Channel A is a connector 250 heading toward the broadcast tower. Below the filter connector 204 for Channel G is a line terminator 260. The connector sections 204 can be tee junctions. Coaxial stub terminators such as terminator 260 can include an internal short circuit placed at an appropriate electrical distance an associated junction that the resultant reactive circuit, viewed from the electrical center of the associated junction, appears as an infinite impedance.

In the example of FIG. 2, the lengths vertical adjustment sections 210, 220, and 230 can be used to achieve realize the required port impedance translations in odd multiples of one-quarter wavelength for each channel from the out-of-band-signal-short-circuit output-side loci for respective channel filters 102. See U.S. Pat. No. 7,864,001.

In the example of FIG. 2, the linkages of the reconfigurable manifold combiner are rectilinear. In practice, a reconfigurable manifold combiner can be achieved in any combination of linear and/or non-linear segments, and segments can be joined at any angle. Reconfigurable manifold combinations can be substantially planar, e.g., where the lengths of the manifold components are arranged in a single plane. The plane can be along where the outputs of channel filters are aligned. Alternatively, a reconfigurable manifold combiner can be constructed in three dimensions.

In practice a reconfigurable manifold combiner, such as the one depicted in FIG. 2, can be made by combining coaxial elements of any shape and size, e.g., including U-shaped elements and asymmetrical elements. However, for interchangeability and rapid reconfiguration, there are advantages, separately and in combination, of keeping the arrangement in a single plane, rectilinear, and consisting of regularly shaped interchangeable parts.

For example, the rectilinear configuration illustrated in FIG. 2 provides the advantage that the lengths of interconnection paths between can be adjusted by varying the lengths of vertical connectors such as connectors 210, 220, and 230, without otherwise altering the manifold. That is, vertical U-sections of the manifold can be adjusted in a manner analogous to manipulating the slide of a trombone to adjust tuning. Vertical connectors such as connectors 210, 220, and 230 can be swapped with pre-selected alternative components, for example, to accommodate a change in carrier frequency for a particular channel. Additionally, or alternatively, vertical connectors such as connectors 210, 220, and 230 can be adjustable to vary lengths depending, for example, on wavelength tuning requirements.

Notably, varying U-section dimensions can be achieved in schema which optimize facility floor space, since the filters 102 themselves do not themselves need to be relocated to achieve reconfiguration of the reconfigurable manifold combiner. The filters can be packed close together.

Reconfigurable manifold combiners can be implemented in a variety of geometric forms. In the example of FIG. 2, for example, the manifold is terminated at one end of the bank of filters at Channel G, and the feed to the tower 250 is at the other end of the bank at Channel A. However, there is no reason terminations and/or ports to the tower antenna could not be placed at other locations, provided the quarter-wavelength impedance translation requirements are met. Similarly, there is no requirement, per se, for the manifold to be arranged linearly, as opposed to, for example, having multiple feeds funneling toward a central tower feed, and, or having one or more sub-combiner sections. Further, a reconfigurable manifold combiner can include multiple antenna feed outputs, e.g., to support two or more antennas or to support an interleaved antenna having two or more inputs.

Third, reconfigurable manifold combiners can be implemented in a variety of station frequency orders. For example, in reference to FIG. 2, there is no requirement for the Channels A through G to be in any particular frequency order. The order of frequencies from Channels A to Channel G could be ascending, descending, or random. Any number of the filters could be populated or left open, e.g., with a stub terminator in place of a filter. Thus, rapid additions or substitutions or filter equipment could be made and any point in the manifold, provided the quarter-wavelength impedance translation requirements are met, e.g., via adjustments to manifold component, such as adjustments to vertical manifold segments or other means. Similarly, there is no requirement that the filters must be together in one bank.

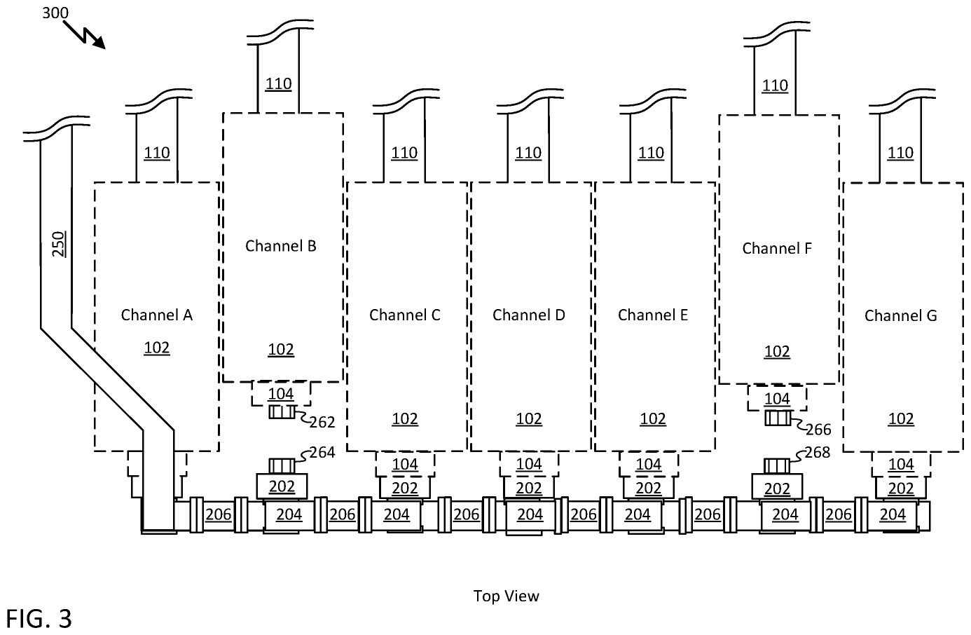

FIG. 3 is top view of an optional configuration of the system of FIG. 2. Here in FIG. 3, not all of the filters are currently connected to the manifold. In the top view, in FIG. 3 we see that each filter 102 also has an individual feed 110 for its signal on top. We see the tower feed 250 heading away from the reconfigurable manifold combiner which is toward the bottom. For Channels A, C, D, E, and G, we see portions of the manifold connectors 202 connected to the outputs 104 of the associated filters 102. The filters for Channels B and F are rolled back from the manifold. In practice, such filters can be set on casters which allow them to be rolled in and out of position, e.g., for installation and/or maintenance. Here the filters 101 for Channels B and F are shown with terminators 262 and 266 respectively, and the associated manifold connectors 202 are shown with terminators 264 and 268. This can be done for a number of reasons. For example, the Channel B and Channel F filters 102 can be spares, e.g., that are ready to use for other channels in case of an actual or anticipated equipment failure of a filter for another station. Similarly, the Channel B and Channel F filters 102 can be held in reserve for future expansion of channels sharing use of the tower. Reconfiguration of the manifold can include simply connecting and disconnecting filters from the manifold, and additionally or alternatively adjusting U-sections of the manifold to accommodate one or more channels being brought online.

### Further Advantages

Reconfigurable manifold combiner s and filter arrangements, such as those illustrated in FIGS. 2 and 3, have several advantages over prior art designs such as those described in U.S. Pat. No. 7,864,001.

First, a reconfigurable manifold allows for easy interchange or adjustment of tuning sections allows rapid reconfiguration. This is important both for reconfiguration of a multi-station broadcast site, e.g., in response to commercial and/or licensing consideration, and for rapid responses to equipment failures.

The movement, replacement, repair, and/or rearrangement of filters themselves can involve significant efforts and delays. Referring to FIGS. 1-3, for the FM radio band, the bank of filters such as bank 100 could be quite large. Each filter 102 can be approximately four feet tall, ten feet long, two feet wide, and weigh 1000 pounds. Space in a multi-station broadcast site can be limited, and physical movement of such heavy equipment within, into, and/or out of facility can be difficult. Therefore, provisioning a facility with spare filter equipment and a reconfigurable manifold can facilitate speedier reconfiguration and/or repairs.

Second, the alternative use of Constant Impedance Filter (CIF) modules to form a combiner can be less efficient, less robust, take up more space, and be most costly. As compared with a coaxial reconfigurable manifold combiner, CIFs typically will take up more facility floor space. CIFs are more complex and hence provide lower reliability and higher signal losses. CIFs can yield lower voltage safety than a coaxial combiner.

A reconfigurable manifold combiner can have several advantages over the alternative Constant Impedance Filter (CIF) modules. Designs of the type illustrated in FIGS. 2 and 3, for example, have the advantages that the signal is always passing through a filter and there is no by-pass mode or band-stop filter for Nav-Com intermodulation suppression.

In contrast, for CIF designs with by-pass there is requirement is to allow a transmitter to bypass its combiner module and feed the broadband port of the opposite channel combiner. When this is done the high-power amplifier (HPA) is operating without the filtering provided by the combiner module. The input to wideband isolation for each module is on the order of −35 dB. This means that each channel in the combiner will apply power to the HPA patched to the wideband port 35 dB down from its carrier power. The turn-around loss of the HPA is assumed to be −20 dB. This means the power of the IM generated in the HPA is on the order of −55 dB from carrier power. The requirement is −85 dB so at least another 30 dB is required. Therefore, to meet the intermodulation requirements, a system using the CIF design requires more equipment than a manifold combiner implementation.

### Failure Prediction and Sensing

Broadcast site equipment can be monitored in a number of ways. For example, forward power, reverse power, and/or resultant VSWR can be monitored at directional couplers. A fold-back or power down alarm can be based on VSWR values, for example. Similarly, internal pressures and temperatures of pieces can be monitored. For example, a pressure sensor on an output splitting hybrid or a combiner could be wired for constant monitoring. A pressure drop could then trigger an automatic fold back condition in one or more transmitters via interlocks. similarly, temperatures of combiner modules can be monitored. For wideband hybrids, for example, a temperature sensor can be mounted on each hybrid/combined output line and the temperature continuously monitored. Any change from the steady state temperature can help identify potential trouble and prevent catastrophic failure. Further, couplings (e.g., at −40 dB) can be made to lines feeding the load to allow for the monitoring of power to the load, and this information can be monitored to detect alarm conditions. Such monitoring of electrical, pressure, and/or thermal conditions can be used to adjust operations, schedule maintenance, trigger emergency shutdowns, and/or initiate equipment switchovers.

Switchovers in response to failure prediction and sensing can be accomplished quickly by reconfiguring a reconfigurable manifold combiner, e.g., in accordance with plans that are pre-established for contingent circumstances using equipment already provided at a multi-station broadcast site. This can include adjusting the lengths of manifold combiner segments, for example, or replacing segments. Similarly, reconfiguration can include adding or removing stubs, or other gear.

Notably, the use of a reconfigurable manifold can permit a new configuration to be accomplished rapidly without requiring moving heavy equipment significant distances. Further, reconfiguration can be automated, e.g., in a sequence of operations in which manifold segments, stubs, tee junctions, and the like are manipulated robotically. Hence reconfiguration can be initiated and/or completed automatically in response to failure prediction and sensing.

### Example Reconfigurations

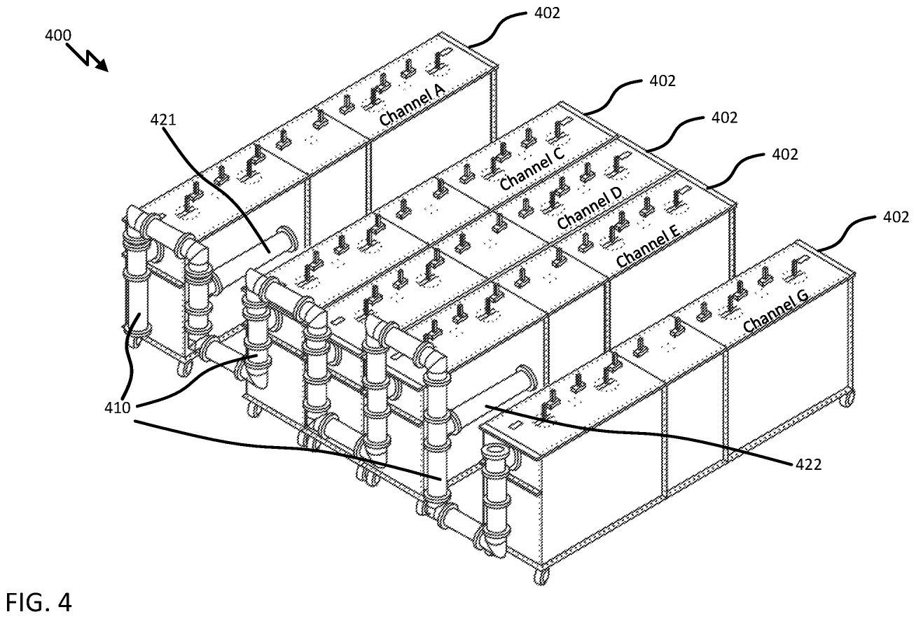

FIGS. 4-10 illustrate a multi-channel manifold configuration and reconfiguration process, whereby the manifold is adjusted to accommodate the addition of channels. Of course, similar processes can be followed to remove channels or to switch out channel equipment for different frequencies of operation. The figures illustrate the general concept. Notably, e.g., for multichannel FM transmission stations where equipment can be heavy and/or cumbersome, manifolds like those illustrated in FIGS. 4-10 can be adjusted to permit easy service, repairs, exchanges, additions, or removals of filter gear without requiring any changes to the inputs to the filters or relocation of any equipment not directly involved in the operations done for a given channel.

FIG. 4 shows a seven-channel configuration 400 for a transmitting station. In the example of FIG. 4, five filters 402 are in place, and space is reserved for two more, where Channels A, C, D, E, and G are installed, and there is room for Channel B and Channel F to be inserted. To the top right of FIG. 4, not shown, are the input ports for the filters 402. To the bottom left of FIG. 4 are the filter outputs which are connected to a reconfigurable manifold combiner 410. The manifold 410 consists mostly of tubular sections lying the plane of aligned output ends of the filters. The manifold 410 also include connections to the five Channels A, C, D, E, and G, and stubs 421 and 422 which terminate the manifold at the positions held in reserve for Channels B and F.

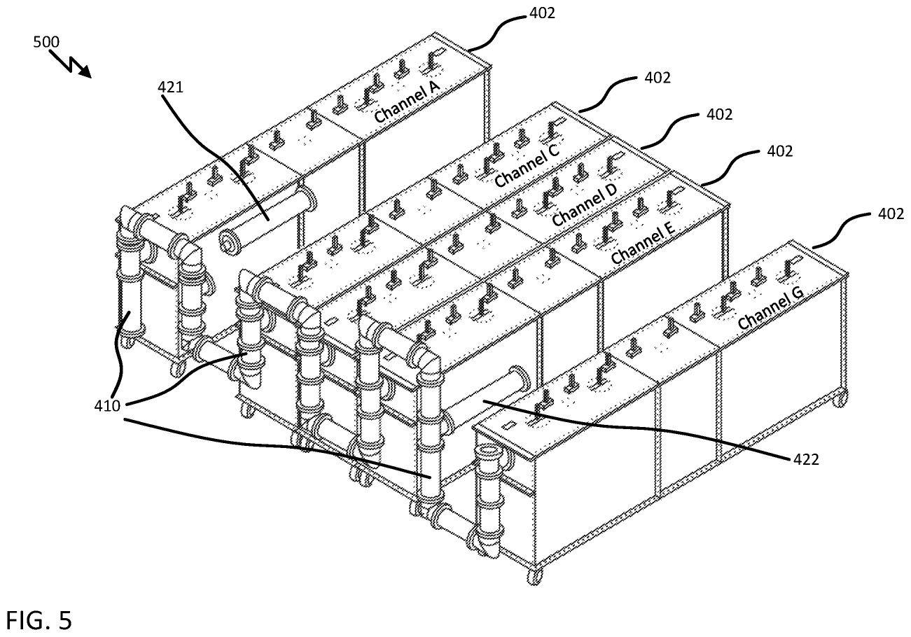

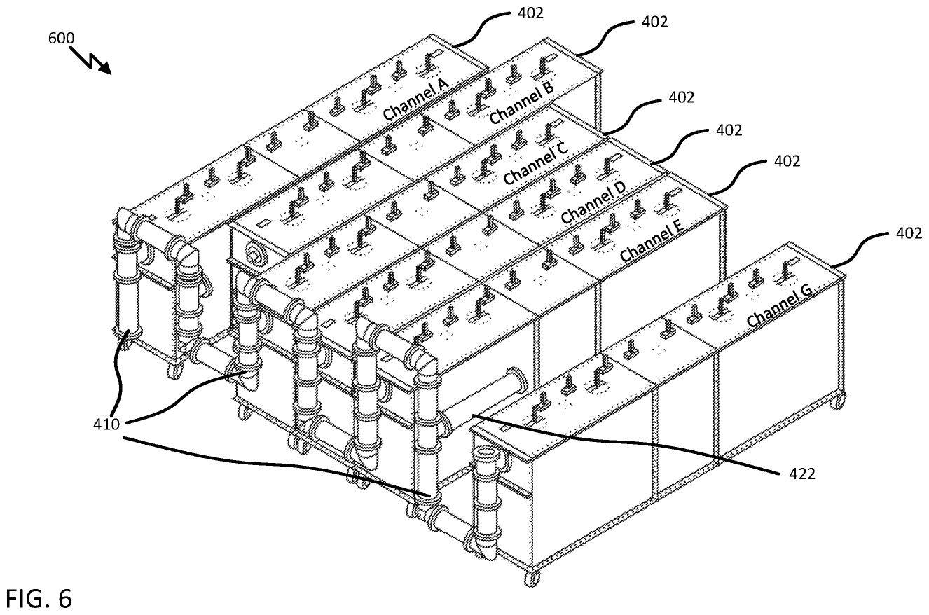

FIG. 5 shows a configuration 500 in a process of modifying the manifold 410 of FIG. 4. Here in FIG. 5, the stub 421 on the Channel B port is being removed. The next step is shown in configuration 600 of FIG. 6, where filter 402 for Channel B is being rolled into place.

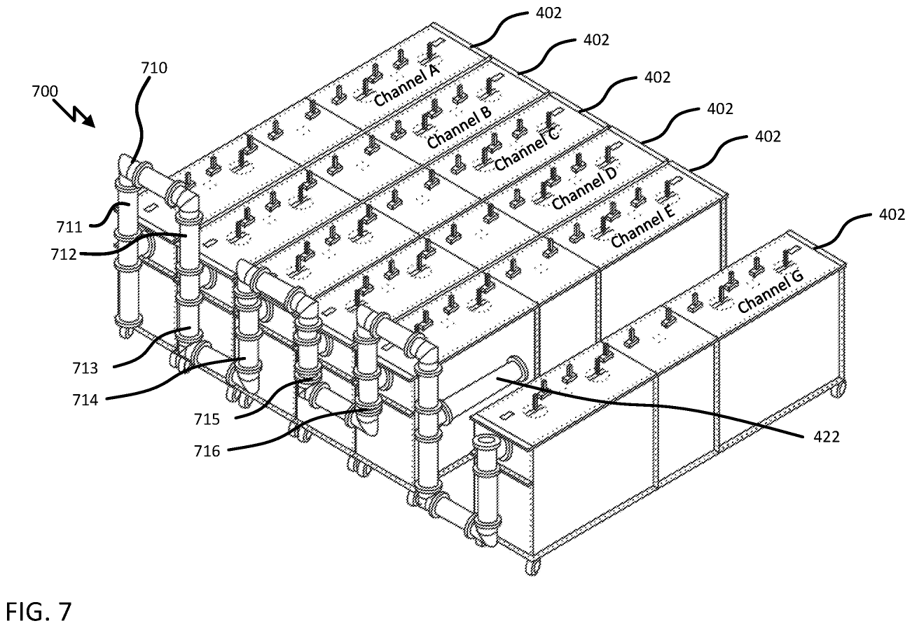

In FIG. 7, channel B has been connected to a manifold 710. Manifold 710 is similar to manifold 410 with some adjustments. Relative to manifold 410, in manifold 710 manifold sections 711-716 have been adjusted. Adjustment of manifold sections can be achieved, for example, by adding, removing, or adjusting the physical lengths or electrical characteristics of component pieces of the manifold. In the example of FIG. 7, sections 711 and 712 can have been added to lengthen the manifold between the outputs of the filters 402 for Channel A and Channel B. Sections 713 and 714 can be adjustable sections that have been lengthened. For sections 715 and 716, parts of the manifold can have been removed, and the manifold closed using the couplings to the removed parts In FIG. 7, the configuration 700 now includes six channels A-E and G connected to adjusted manifold 710.

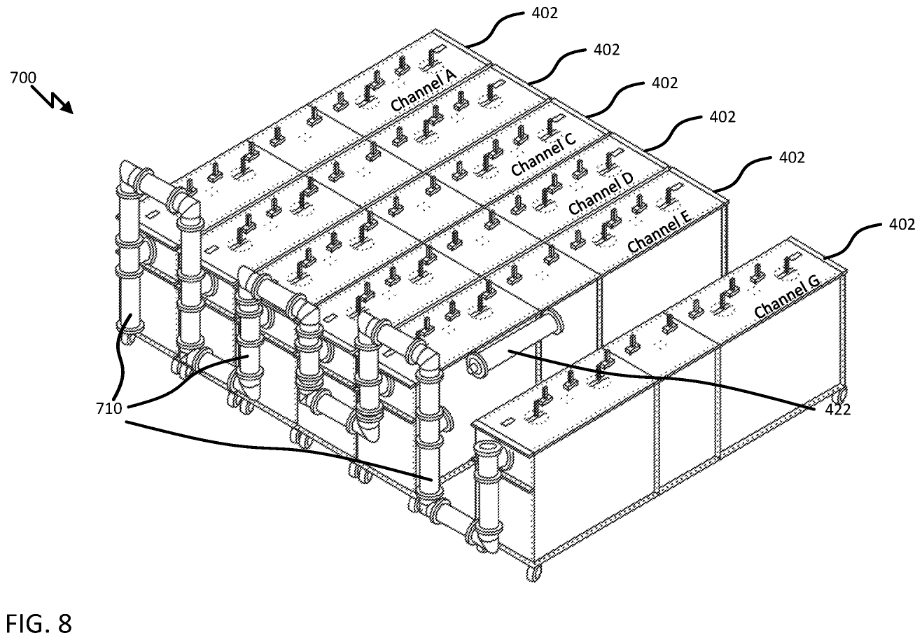

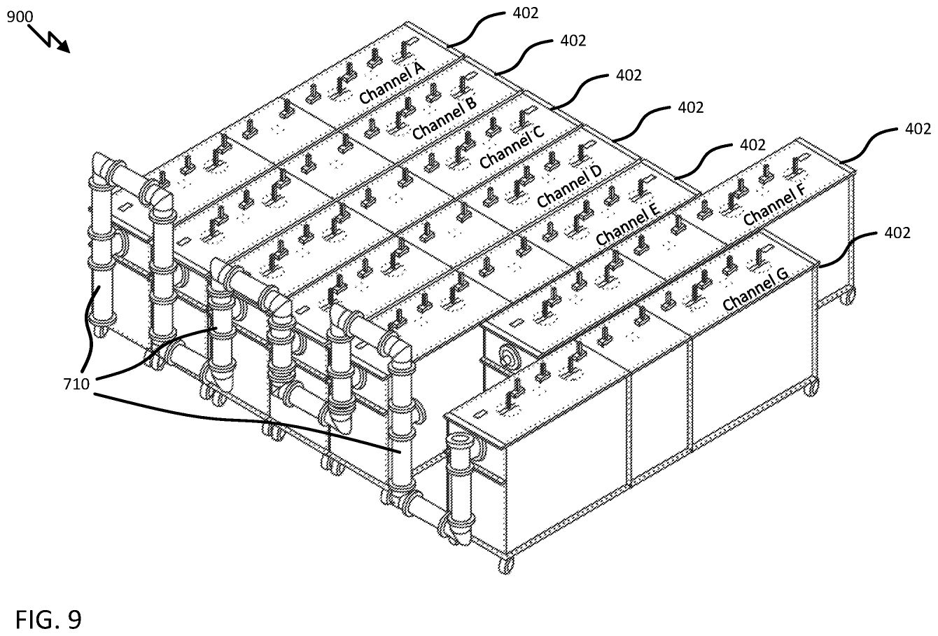

FIG. 8 shows a configuration 800 in which the configuration 700 of FIG. 7 is being altered to make room for Channel F. In FIG. 8, the stub 422 for Channel F is being removed. In configuration 9 of FIG. 9, the next step is shown, where a filter 402 for channel F is being rolled into place.

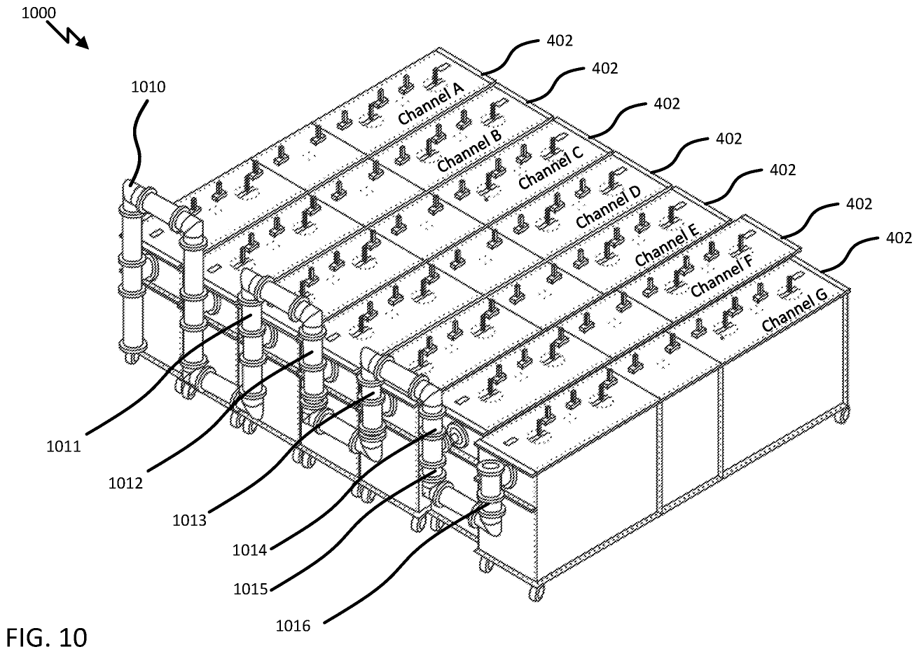

In configuration 1000 of FIG. 10, filter 402 of channel F is about to be connected to an adjusted manifold 1010. Manifold 1010 is the manifold 410 of FIG. 4, adjusted as described in connection to FIG. 7, and here further adjusted at sections 1011-1016. As compared to manifold 710 of FIG. 7, here sections 1011 and 1012 have been lengthened, sections 1013-1016 have been shortened, e.g., by either adjustment or substitutions in those parts of the manifold 1010.

### Joining Multiple Reconfigurable Manifold Combiners

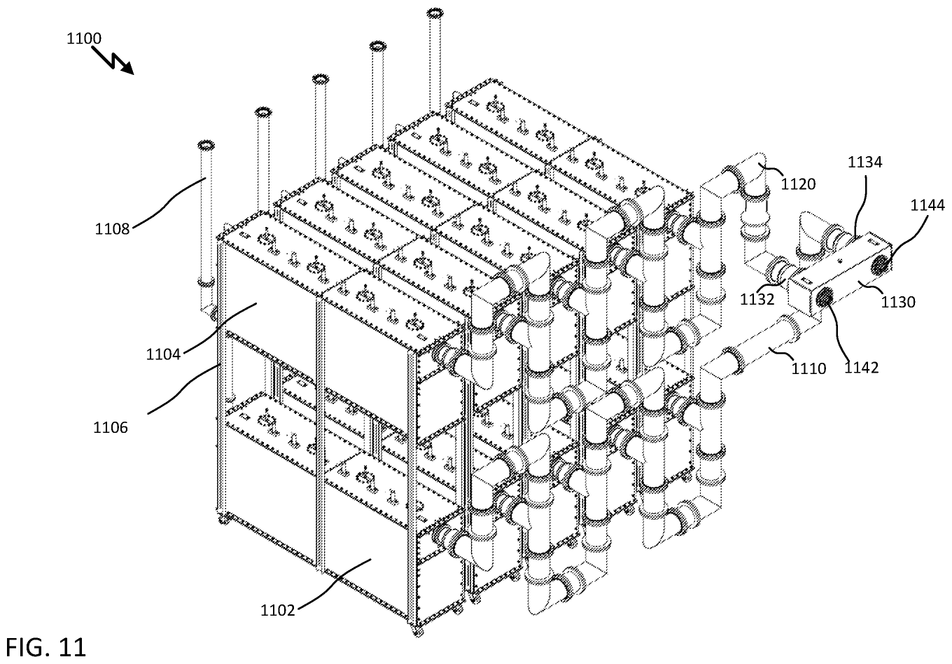

FIG. 11 shows an installation 1100 with a dual reconfigurable manifold including a lower reconfiguration manifold 1110 and an upper reconfigurable manifold 1120 feeding into an output hybrid coupler 1130. Installation 1100 is a five-channel system. Five feeds 1108 are split by coaxial tee connectors (not visible behind the filters in FIG. 11) to feed five pairs of filters, with each pair of filters including a lower filter 1102 and an upper filter 1104. The lower manifold 1110 combines inputs from the five lower filters 1102, and the upper manifold 1120 combines inputs the from five upper filters 1104. The upper bank of filters 1104 is supported by beams 1106.

A dual reconfigurable manifold arrangement, such as the one depicted in FIG. 11, has many advantages over the use of standard constant impedance filters (CIFs). First, the input to each pair of filters can be accomplished with a simple coaxial tee connector, rather than the input hybrids that would be required for each frequency in the chain. The coaxial tee is easier to manufacture plus has power and peak power advantages. In addition, the output of each frequency no longer needs a hybrid. For example, a five-channel system using CIF technology would require at least ten hybrids. In contrast, the five-channel dual manifold system shown in FIG. 11 requires only the one output hybrid 1130.

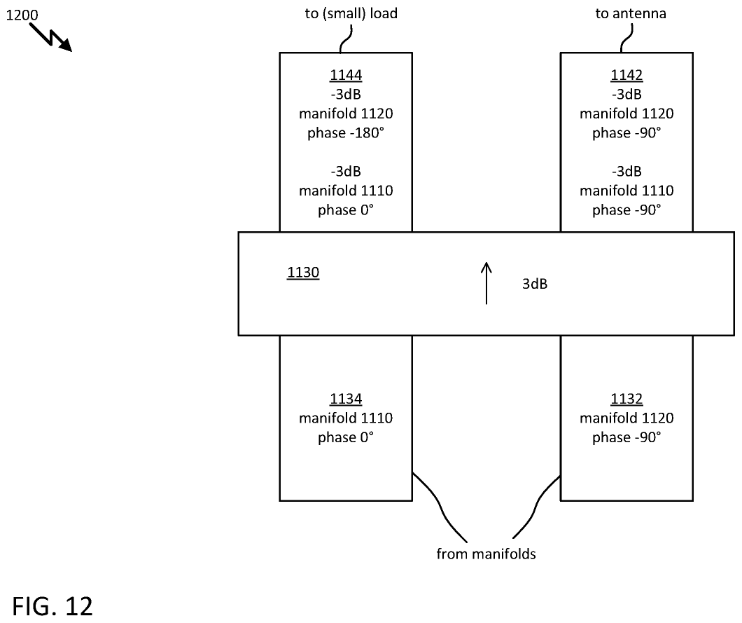

FIG. 12 illustrates an example configuration 1200 using the hybrid coupler 1130 of FIG. 11. Hybrid 1130 is a 90-degree 3 dB hybrid coupler. With reference to FIG. 11, here in FIG. 12, the hybrid 1130 is fed at point 1134 by manifold 1110, and at point 1132 by manifold 1120. The feed from manifold 1120 is at −90 degrees relative to manifold 1110. After passing through hybrid 1130, the manifold feeds yield at point 1142 two −3 dB vectors that are of equal amplitude and in phase. An antenna connected to point 1142 is thus provided full power. In contrast, at point 1144, the contribution vectors from the two manifolds are now of equal amplitude but opposite phase, out by 180 degrees. Therefore little or no power is provided to a load connected to point 1144.

Another advantage of the dual manifold combiner is that it allows compact installation. With space constraints being a factor in most buildings, designs like that illustrated in FIG. 11 is very attractive to the broadcasters.

Further, dual reconfigurable manifold combiners enjoy all the versatility of single reconfigurable combiners. For example, as described in reference to FIGS. 1-10, changes in channel frequencies can be easily accommodated, as well as the removal, addition, or substitution of channels and/or channel equipment.

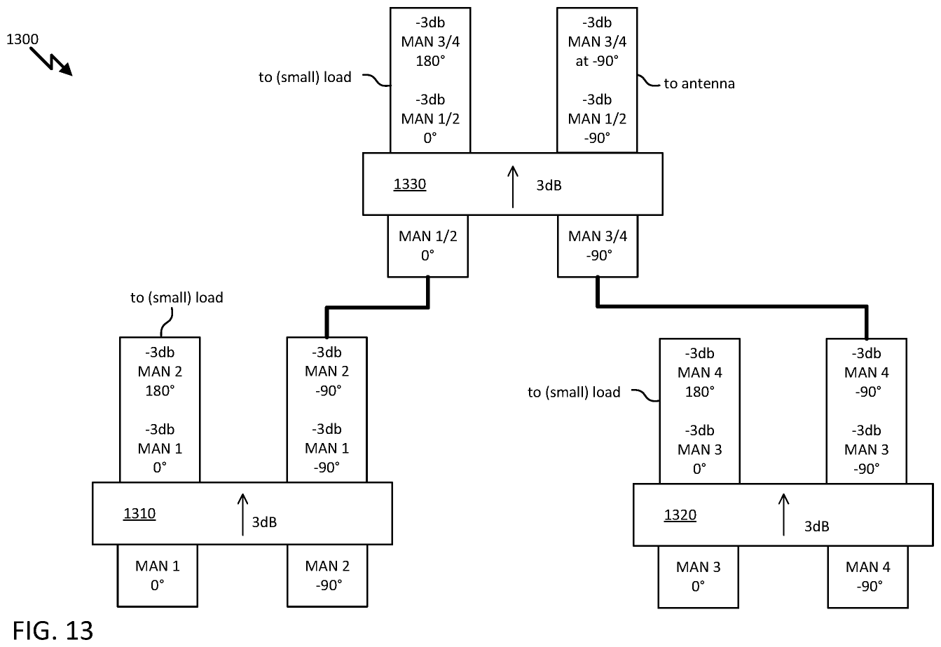

Multiple reconfigurable manifold combiners, e.g., having 3, 4, 5 or more manifolds, can be joined through hybrid couplers. FIG. 13 illustrates and an arrangement 1300 of three 3 dB hybrid couplers 1310, 1320, and 1340, which join feed from four manifolds MAN 1 through MAN 4 to feed a single antenna. As in FIG. 12, here in FIG. 13, the technique is to bring in feeds that are 90 degrees out of phase and exploit the phase shifts of 3 dB hybrids to rejoin, at one output, and cancel, at another output, the incoming feeds to provide the rejoined signal to the antenna. In FIG. 12, this is done with one hybrid in a single stage. In FIG. 13, this is done with three hybrids in two stages of hybrids. In FIG. 13 the phases illustrated are relative to each other at a given hybrid coupler, rather than across all three hybrid couplers.

The techniques illustrated in FIGS. 11-13 can be used to join any odd or even number of manifolds, subject to the limitations of the losses in the hybrids.

What is claimed is:

1. A filter bank for a multi-station broadcast site, the filter bank comprising:
a plurality of station input ports;
a plurality of bandpass filters, wherein each bandpass filter comprises an input port and an output port, the input port of the bandpass filter being connect to a single station input port, and wherein each bandpass filter behaves as a short circuit at specified locations to frequencies outside a passband for a station associated with bandpass filter; and
a configurable manifold combiner, the configurable manifold combiner comprising:
a plurality of coaxial tee junctions, each coaxial tee junction comprising an input port and two output ports;
a plurality of manifold sections, each manifold section comprising a coaxial section having a length;
one or more coaxial stub terminations, each coaxial stub termination comprising an input port and an internal short circuit disposed at a distance from the input port of the stub termination; and
an antenna output port comprising an input port, an output port, and a coaxial section having a length,
wherein:
the input port of each coaxial tee junction is connected either to the output port of one of the bandpass filters, or to the input port of one of the coaxial stub terminations;
each output port of each of the coaxial tee junctions is connected either to one of the manifold sections, one of the coaxial stub terminations, or the antenna output port; and
an electrical performance of the configurable manifold combiner can be adjusted by adjustment or substitution of one or more of the manifold sections.

2. The filter bank of claim 1, wherein the lengths of the manifold sections lie substantially in a single plane.

3. The filter bank of claim 2, wherein the manifold sections are either vertical sections, horizontal sections, U-connector sections, or components of U-connector sections, such that the reconfigurable manifold combiner is a substantially rectilinear coaxial structure lying in the single plane.

4. The filter bank of claim 3, wherein the electrical performance of the configurable manifold combiner can be adjusted by adjusting the length of one or more manifold segments.

5. The filter bank of claim 4, wherein the electrical performance of the configurable manifold combiner can be adjusted by adjustment of the one or more of the vertical sections, without adjustment of the horizontal sections, U-connector sections, or components of U-connector sections.

6. The filter bank of claim 3, wherein the electrical performance of the configurable manifold combiner can be adjusted by substituting one or more of the manifold segments with one or more new segments of a different length.

7. The filter bank of claim 1, wherein the electrical performance of the configurable manifold combiner can be adjusted without physical movement of any of the bandpass filters.

8. The filter bank of claim 1, wherein the electrical performance of the configurable manifold combiner can be adjusted without alteration of any of the station input ports.

9. The filter bank of claim 1, wherein the electrical performance of the configurable manifold combiner can be adjusted without alteration of any of the bandpass filters.

10. The filter bank of claim 2, wherein, the output port of each bandpass filter is aligned in the single plane.

11. The filter bank of claim 2, wherein, the bandpass filters are aligned perpendicular to the single plane.

12. The filter bank of claim 11, wherein the bandpass filters abut.

13. The filter bank of claim 1, wherein the stations operate in an AM, FM, VHF, UHF, or cellular communications band.

14. The filter bank of claim 1, being implemented without any Constant Impedance Module (CIF).

15. A radio system, comprising a plurality of the filter banks of claim 1 and one or more 3 dB hybrid couplers for joining the antenna output ports of at least two of the filter banks into a joined antenna feed.
